(19) United States
(12) Patent Application Publication
(10) Pub. No.: US 2021/0320107 A1
(43) Pub. Date: Oct. 14, 2021

(54) SEMICONDUCTOR STRUCTURE AND FABRICATION METHOD THEREOF

(71) Applicant: CHANGXIN MEMORY TECHNOLOGIES, INC., Hefei (CN)

(72) Inventors: Er Xuan PING, Hefei (CN); Zhen ZHOU, Hefei (CN)

(21) Appl. No.: 17/356,521

(22) Filed: Jun. 24, 2021

Related U.S. Application Data
(63) Continuation of application No. PCT/CN2020/102476, filed on Jul. 16, 2020.

(30) Foreign Application Priority Data
Dec. 6, 2019 (CN) 201911239722.1

(51) Int. Cl. H01L 27/108

(52) U.S. Cl. CPC H01L 27/10814; H01L 27/10855

(57) ABSTRACT

The embodiments provide a semiconductor structure and a fabrication method thereof. The semiconductor structure includes: a substrate including an active region and a shallow trench isolation region spaced apart from each other; a plurality of isolation structures arranged on a surface of the substrate; a plurality of grooves arranged between the plurality of isolation structures, wherein a bottom of the groove has a first inclined plane, and the first inclined plane is formed in the active region; and a conductive plug arranged in the groove. According to embodiments of the present disclosure, it is avoidable that an air gap is formed inside a polycrystalline silicon in the fabrication process of a storage node contact (SNC) structure.

### CROSS REFERENCE

This application is a continuation of PCT/CN2020/102476, filed on Jul. 16, 2020, which claims priority to Chinese Patent Application No. 201911239722.1, titled “SEMICONDUCTOR STRUCTURE AND FABRICATION METHOD THEREOF” and filed on Dec. 6, 2019, the entire contents of which are incorporated herein by reference.

### TECHNICAL FIELD

The present disclosure relates to the field of semiconductor fabrication technologies, and more particularly, to a semiconductor structure that can avoid forming an air gap and a fabrication method thereof.

### BACKGROUND

A storage node contact (SNC) structure is a contact structure for connecting transistors and storage capacitors in a DRAM structure. Generally, the SNC is a polycrystalline silicon. Generally, a bottom of the SNC is connected to a substrate and a shallow trench isolation (STI) structure, a top thereof is connected to metal, and sidewalls thereof are sidewalls of the isolation structure. The isolation structure is, for example, a bit line structure or a dielectric layer structure.

In the related technologies, the bit line structure is fabricated in advance, and thus it is required to fabricate the dielectric layer structure as the isolation structure to fabricate the other two sidewalls of the SNC trench, and the polycrystalline silicon is filled into the trench to fabricate the SNC. Due to larger hardness, the sidewalls of the dielectric layer can only be fabricated by deposition. As a result, the trench between the sidewalls of the dielectric layer formed by deposition is generally a trapezoidal structure (with reference to FIG. 3 of the specification), which is narrow at the top and wide at the bottom. Therefore, it is difficult to control uniformity of the deposition in the deposition process of the polycrystalline silicon, such that air gaps may be easily formed inside the SNC, which causes changes of electrical properties of the SNC, leads to component failure, and reduces the yield.

### SUMMARY

An objective of the present disclosure is to provide a semiconductor structure and a fabrication method thereof, to overcome, at least to a certain extent, the problem of forming an air gap inside a polycrystalline silicon in the process of fabricating an SNC structure due to limitations of related technologies.

According to some embodiments of the present disclosure, there is provided a semiconductor structure, which includes:

a substrate including an active region and a shallow trench isolation region spaced apart from each other;

a plurality of isolation structures arranged on a surface of the substrate;

a plurality of grooves arranged between the plurality of isolation structures, a bottom of the groove having a first inclined plane, and the first inclined plane being formed in the active region; and

a conductive plug arranged in the groove.

In an exemplary embodiment of the present disclosure, a top area of the groove is smaller than a bottom area thereof

In an exemplary embodiment of the present disclosure, an inclination angle of the first inclined plane is 30°-40°.

In an exemplary embodiment of the present disclosure, the bottom of the groove further has a second inclined plane formed in the shallow trench isolation region.

In an exemplary embodiment of the present disclosure, the inclination angle of the second inclined plane is 20°-60°.

In an exemplary embodiment of the present disclosure, the isolation structure includes a bit line structure and a dielectric layer structure.

In an exemplary embodiment of the present disclosure, cross sections of the plurality of grooves include one or more of a square, a polygon, a circle, or an ellipse.

In an exemplary embodiment of the present disclosure, the plurality of grooves are arranged in an array.

In an exemplary embodiment of the present disclosure, the first inclined plane is a cambered surface.

According to some embodiments of the present disclosure, there is provided a method for fabricating a semiconductor structure, which includes:

providing a substrate, the substrate including an active region and a shallow trench isolation region spaced apart from each other;

forming a sacrificial layer material on a surface of the substrate;

etching a part of the sacrificial layer material to form a plurality of first grooves;

after depositing a dielectric layer on the first groove, removing the remaining sacrificial layer material to form a plurality of second grooves;

etching down an exposed part of the active region at a bottom of the second groove to form a first inclined plane; and

performing an epitaxial silicon growth process in the second groove by taking the first inclined plane as a substrate to fill the second groove.

In an exemplary embodiment of the present disclosure, an inclination angle of the first inclined plane is 30°-40°.

In an exemplary embodiment of the present disclosure, after the first inclined plane is etched, the first inclined plane is subjected to natural oxide removal treatment and/or carbon-based residue removal treatment.

In an exemplary embodiment of the present disclosure, the etching down an exposed part of the active region at a bottom of the second groove to form a first inclined plane further includes:

simultaneously etching an exposed part of the shallow trench isolation region adjacent to the exposed part of the active region to form a second inclined plane.

In an exemplary embodiment of the present disclosure, an etching selectivity of the exposed part of the active region with respect to that of the exposed part of the shallow trench isolation region is 1:1.

In an exemplary embodiment of the present disclosure, the inclined planes are etched using sulfur hexafluoride gas.

In an exemplary embodiment of the present disclosure, the performing an epitaxial silicon growth process in the second groove includes:

setting a hydrochloric acid flow rate as 150 sccm±30%.

In an exemplary embodiment of the present disclosure, the performing an epitaxial silicon growth process in the second groove includes:

after filling the second groove, removing a polycrystalline silicon by using a wet process to leave only a monocrystalline silicon, and trimming a top of the filled silicon to be a flat plane.

In an exemplary embodiment of the present disclosure, after filling the second groove, the fabrication method further includes:

depositing metal on a surface of the filled silicon.

According to the embodiments of the present disclosure, an inclined plane is arranged in the exposed part of the active region at the bottom of the groove containing the SNC structure, and the polycrystalline silicon is grown inside the groove by taking the inclined plane as a substrate. In this way, the SNC structure containing no air gap can be quickly formed, a component failure rate can be reduced, and a yield rate can be enhanced.

It is to be understood that the above general description and the detailed description below are merely exemplary and explanatory, and do not limit the present disclosure.

### BRIEF DESCRIPTION OF THE DRAWINGS

The accompanying drawings herein are incorporated in and constitute a part of this specification, illustrate embodiments conforming to the present disclosure and, together with the description, serve to explain the principles of the present disclosure. Apparently, the accompanying drawings in the following description show merely some embodiments of the present disclosure, and persons of ordinary skill in the art may still derive other drawings from these accompanying drawings without creative efforts.

FIG. 1 illustrates a schematic diagram of an arrangement mode of an SNC structure according to an exemplary embodiment of the present disclosure;

FIG. 2 illustrates a schematic diagram of another arrangement mode of the SNC structure according to an exemplary embodiment of the present disclosure;

FIG. 3 illustrates a schematic diagram of a fabrication process of the SNC structure in the related technologies;

FIG. 4 illustrates a schematic diagram of a semiconductor structure according to an embodiment of the present disclosure;

FIG. 5 illustrates a flowchart of a method for fabricating the SNC structure according to an embodiment of the present disclosure;

FIG. 6A to FIG. 6D illustrate schematic process diagrams of steps as shown in FIG. 5;

FIG. 7A and FIG. 7B are schematic diagrams illustrating shapes of inclined planes of the SNC structure according to an embodiment of the present disclosure;

FIG. 8A and FIG. 8B are schematic cross-sectional views illustrating shapes of the inclined planes of the SNC structure from another angle according to an embodiment of the present disclosure;

FIG. 9A illustrates schematic diagram I showing an undesirable effect of polycrystalline silicon growth;

FIG. 9B illustrates schematic diagram II showing an undesirable effect of polycrystalline silicon growth; and

FIG. 10 illustrates a schematic diagram of the SNC structure after performing a recess etch process.

### DETAILED DESCRIPTION

Exemplary embodiments will now be described more comprehensively with reference to the accompanying drawings. However, the exemplary embodiments can be embodied in many forms and should not be construed as being limited to the embodiments set forth herein. Rather, these embodiments are provided so that the present disclosure will be thorough and complete, and the concepts of these exemplary embodiments will be fully conveyed to those skilled in the art. The described features, structures, or characteristics may be combined in any suitable manner in one or more embodiments. In the following description, numerous details are provided to provide a thorough understanding of the embodiments of the present disclosure. However, those skilled in the art will recognize that the technical solution of the present disclosure may be practiced without one or more of the details described, or that other methods, components, devices, steps, etc. may be employed. In other instances, well-known technical solutions are not shown or described in detail to avoid obscuring aspects of the present disclosure.

Furthermore, the accompanying drawings are merely schematic illustrations of the present disclosure. Same or similar parts are denoted by same reference numbers in the drawings and, thus, a detailed description thereof will be omitted. Some block diagrams shown in the figures are functional entities and not necessarily to be corresponding to a physically or logically individual entities. These functional entities may be implemented in software form, or implemented in one or more hardware modules or integrated circuits, or implemented in different networks and/or processor apparatuses and/or microcontroller apparatuses.

A detailed description of the exemplary embodiments of the present disclosure will be made in the following with reference to the accompanying drawings.

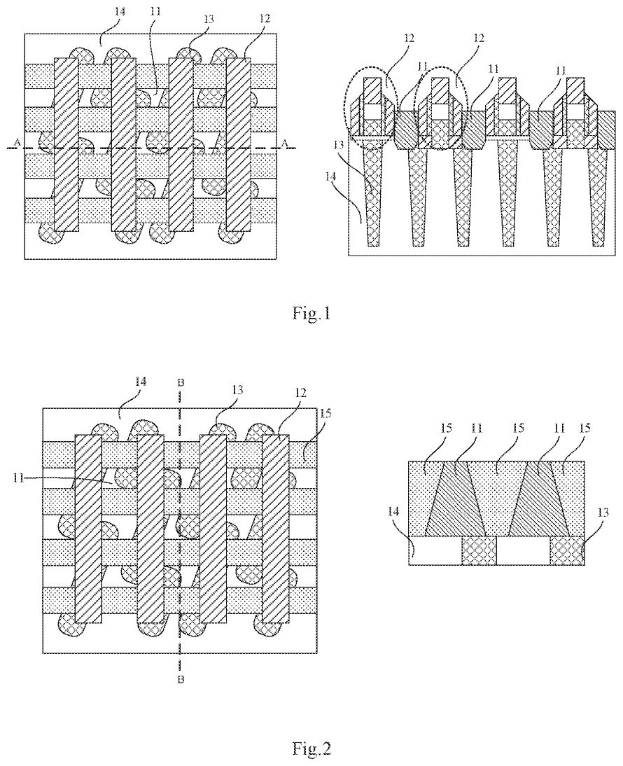

FIG. 1 illustrates a schematic diagram of an arrangement mode of an SNC structure according to an exemplary embodiment of the present disclosure.

The structure on the right side of FIG. 1 is a cross-sectional view along Position A-A of the structure as shown on the left side of FIG. 1. In a DRAM structure, the Position A-A is perpendicular to a bit line (BL) and parallel to a word line (WL). In FIG. 1, a storage node contact (SNC) structure 11 is arranged between sidewalls of two bit line structures 12 at corresponding positions in two adjacent rows of word lines, and a bottom of the SNC structure 11 is connected to an active region 14 and a shallow trench isolation (STI) structure 13.

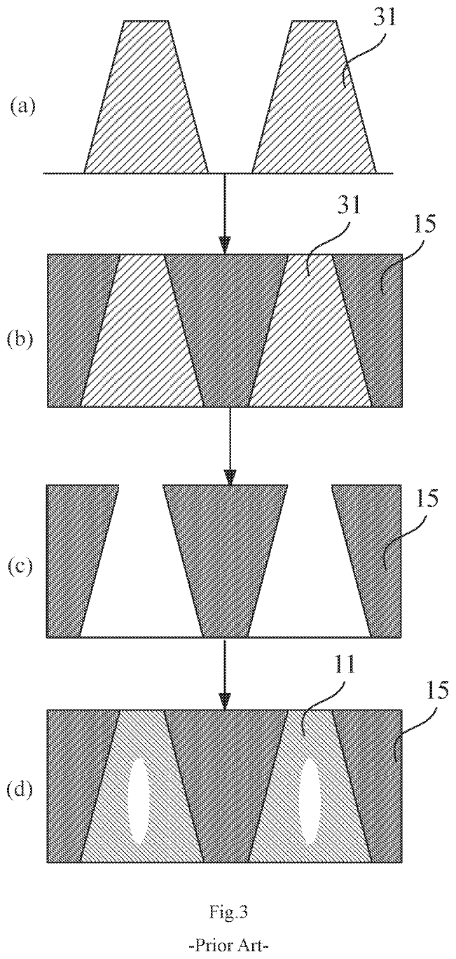

FIG. 2 illustrates a schematic diagram of another arrangement mode of the SNC structure according to an exemplary embodiment of the present disclosure.

The structure on the right side of FIG. 2 is a cross-sectional view along Position B-B of the structure as shown on the left side of FIG. 2. In the DRAM structure, the Position B-B is perpendicular to the word line (WL) and is parallel to the bit line (BL). The adjacent SNC structures are isolated by an isolation structure 15, which includes a dielectric layer structure. It is to be understood that similar to FIG. 1, the storage node contact (SNC) structure 11 in FIG. 2 is still connected, at the bottom thereof, to the active region 14 and the shallow trench isolation structure 13. It is to be understood that, by moving Line B-B, cross-sectional positions are different, such that proportions of the active region 14 and the shallow trench isolation structure 13 in the cross section are different. In the embodiments of the present disclosure, for the sake of simplicity, only the regional positions and proportions as shown in FIG. 2 are employed, but the present disclosure is not limited thereto.

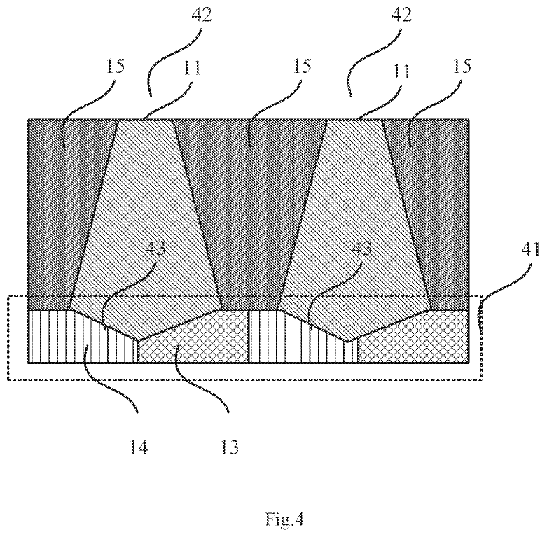

FIG. 3 illustrates a schematic diagram of a fabrication process of the SNC structure in the related technologies.

With reference to FIG. 3, the isolation structure between the SNC structures includes a bit line structure and a dielectric layer sidewall, and thus it is required to form the dielectric layer sidewall when fabricating a groove for containing the SNC structures. However, due to larger hardness, generally the dielectric layer sidewall is difficult to be formed by etching. Therefore, in the related technologies, generally a trench is fabricated (as shown in Step a) by etching a sacrificial layer material 31 (which is generally an oxide, such as silicon dioxide, BPSG, BSG, and so on) in the Direction B-B as shown in FIG. 2, and a dielectric layer structure 15 is fabricated (as shown in Step b) by using a deposition technology. Next, the remaining sacrificial layer material 31 is removed (as shown in Step c), and a polycrystalline silicon is deposited between the dielectric layer structures 15 to fabricate the SNC structure 11 (as shown in Step d). It is to be understood that there exists an isolation structure (such as the isolation structure 12 on the right side of FIG. 1) including the bit line structure in the front and rear of the viewing direction in the figures, and the isolation structure including the bit line structure generally is formed before the dielectric layer structure 15 is formed. In this technology, since the sacrificial layer material is etched in Step a, the cross-section of the remaining sacrificial layer material is a trapezoid. That is, the SNC structure finally fabricated is also a trapezoidal cross section which is narrow at the top and wide at the bottom, making it difficult to complete good deposition of the polycrystalline silicon, which often forms air gaps in the SNC structure (as shown in Step d).

To this end, the embodiments of the present disclosure provide a semiconductor structure capable of avoiding forming the air gaps in the SNC structure.

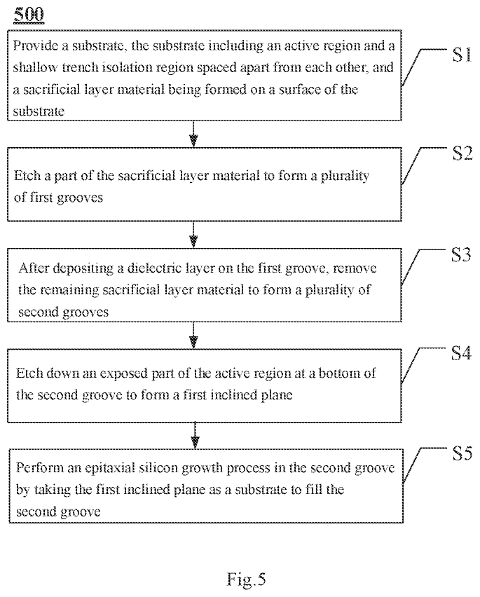

FIG. 4 illustrates a schematic diagram of a semiconductor structure according to an embodiment of the present disclosure.

It is to be noted that FIG. 4 is a cross-sectional view along the Position B-B of the structure as shown on the left side of FIG. 2, and there exists an isolation structure (such as the isolation structure 12 on the right side of FIG. 1) including the bit line structure in the front and rear of the viewing direction in the figures.

With reference to FIG. 4, the semiconductor structure 400 may include:

a substrate 41 including an active region 14 and a shallow trench isolation region 13 spaced apart from each other;

an isolation structure 15 arranged on a surface of the substrate 41;

a plurality of grooves 42 arranged in the isolation structure 15, a bottom of the groove 42 having a first inclined plane 43 formed in the active region 14; and

a conductive plug 11 arranged in the groove 42.

FIG. 4 is a cross-sectional view in the Direction B-B in FIG. 2, the isolation structure 15 marked in FIG. 4 actually is a dielectric layer structure, i.e., the isolation structure 15 on the right side of FIG. 2. However, those skilled in the art may understand that the isolation structure 15 in the embodiments of the present disclosure further includes the bit line structure 12 as shown in FIG. 1, and the bit line structure 12 is in the front or rear of the viewing direction in FIG. 4. That is, the isolation structure 15 in the embodiments of the present disclosure includes four sidewall structures such as two adjacent bit line structures and two adjacent dielectric layer structures, to realize encirclement and isolation of the groove 42.

In the embodiment as shown in FIG. 4, a top area of the groove 42 is smaller than a bottom area thereof, and cross-sectional shapes of the plurality of grooves include one or more of a square, a polygon, a circle, or an ellipse. The plurality of grooves 42 are arranged in an array, wherein the array may be an aligned or staggered dot array. It is to be understood that two opposite sidewalls of the groove 42 are formed by the isolation structure including the bit line structure, and the bit line structure is perpendicular to the substrate. Therefore, a length of a top surface of the groove 42 may be equal to that of a bottom surface thereof, or a width of the top surface of the groove 42 may be equal to that of the bottom surface, which is not particularly limited in the present disclosure.

In one embodiment of the present disclosure, an inclination angle of the first inclined plane 43 may be 30°-40°, for example. Of course, on the active region 14 there may also exist another region. A slope of the other region is different from that of the first inclined plane, which may be, for example, a horizontal region (for example, a bottom shape of the SNC structure 11 in the structure on the right side of FIG. 1). In another embodiment of the present disclosure, the first inclined plane 43 may also be a cambered surface formed in an etching process, which is not particularly limited in the present disclosure.

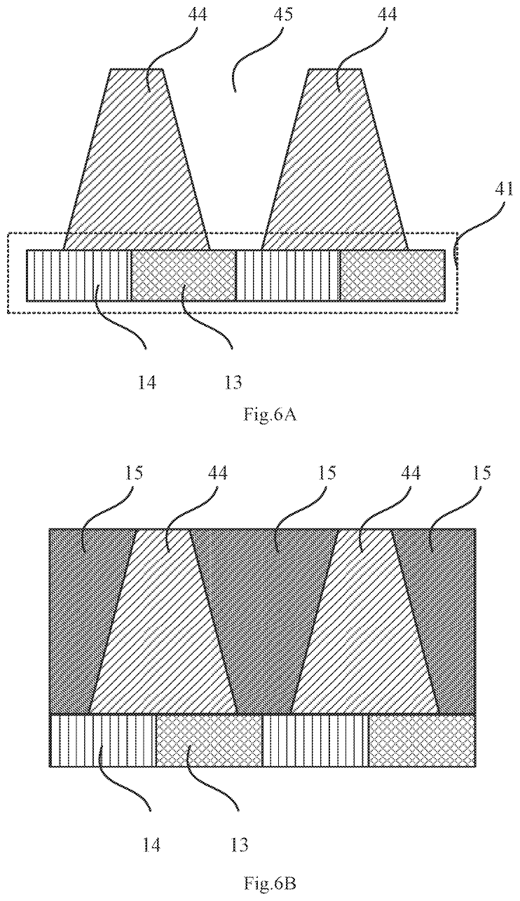

FIG. 5 illustrates a flowchart of a method for fabricating the semiconductor structure as shown in FIG. 4.

With reference to FIG. 5, the method 500 for fabricating the semiconductor structure may include:

Step S1: providing a substrate, the substrate including an active region and a shallow trench isolation region spaced apart from each other, and forming a sacrificial layer material on a surface of the substrate;

Step S2: etching a part of the sacrificial layer material to form a plurality of first grooves;

Step S3: after depositing a dielectric layer on the first groove, removing the remaining sacrificial layer material to form a plurality of second grooves;

Step S4: etching down an exposed part of the active region at a bottom of the second groove to form a first inclined plane; and

Step S5: performing an epitaxial silicon growth process in the second groove by taking the first inclined plane as a substrate to fill the second groove.

In the embodiments of the present disclosure, the sacrificial layer is, for example, an oxide layer, including but not limited to materials such as oxide (such as silicon dioxide), BPSG, BSG, and the like. The first groove is, for example, an inverted trapezoidal groove which is wide at the top and narrow at the bottom, and the second groove is, for example, a trapezoidal groove which is narrow at the bottom and wide at the top. Those of ordinary skill in the art should understand that a non-inverted trapezoidal first groove may also be formed here, wherein a shape of the first groove is determined by factors such as technology means and technological conditions; and the second groove may also be a non-trapezoidal groove, wherein a shape of the second groove is related to the shape of the first groove.

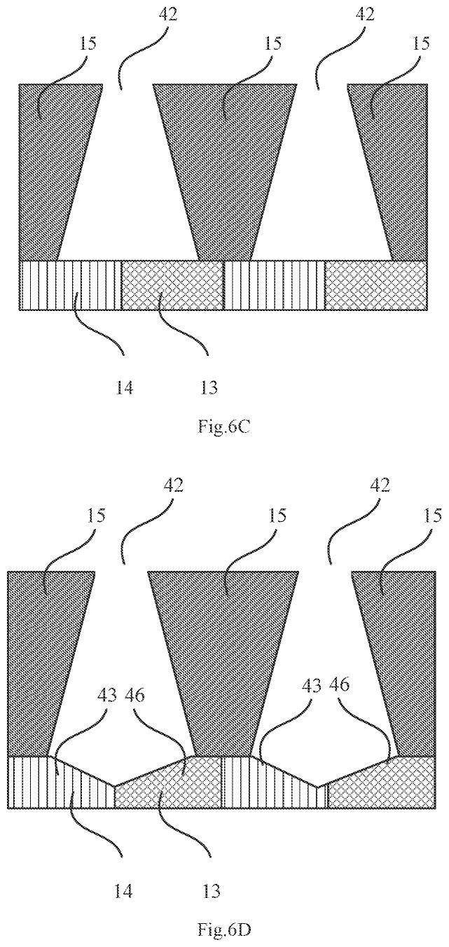

FIG. 6A to FIG. 6D illustrate schematic process diagrams of the steps as shown in FIG. 5.

Similar to FIG. 2 and FIG. 4, for the sake of simplicity, the positions and proportions of the active regions and the shallow trench isolation regions in FIG. 6A to FIG. 6D are merely for the purpose of illustration, and are not intended to limit the positions and proportions of the active regions and the shallow trench isolation regions in the actual processes.

Referring to FIG. 6A, similar to Step (a) in FIG. 3, in the embodiments of the present disclosure, the first groove 45 is also etched on the sacrificial layer 44 to make preparations for the subsequent fabrication of the isolation structure. The active region 14 and the shallow trench isolation region 13 are exposed at the bottom of the first groove 45 at the same time. At this moment, the bit line structures in the front or rear of the viewing direction of the figures generally have already been formed. Therefore, the step as shown in FIG. 6A actually refers to filling the sacrificial layer between the bit line structures and then etching the first groove 45 in the sacrificial layer. That is, two sidewalls in the front and rear of the viewing direction of the first groove 45 are perpendicular to each other and are formed by the isolation structure including the bit line structure.

Referring to FIG. 6B, similar to Step (b) in FIG. 3, in the embodiments of the present disclosure, the isolation structure 15 is fabricated in the same way by depositing a dielectric layer, wherein a material of the dielectric layer is, for example, silicon nitride.

Referring to FIG. 6C, similar to Step (c) in FIG. 3, in the embodiments of the present disclosure, space is created for the fabrication of the SNC also by removing the sacrificial layer 44 to form the second groove 42, and the active region 14 and the shallow trench isolation region 13 are exposed at the bottom of the second groove 42 at the same time. It is to be noted that as can be seen from FIG. 2, as the cross-sectional positions are different (that is, the Line B-B moves transversely), the proportions of the active region and the shallow trench isolation region exposed at the bottom of the second groove 42 actually are different. Therefore, although the embodiments of the present disclosure merely show one type of exposed state of the active region and the shallow trench isolation region, in practical applications, the active region and the shallow trench isolation region may have many types of exposed states.

Referring to FIG. 6D, in the embodiments of the present disclosure, the SNC is fabricated by means of an epitaxial silicon growth process. Therefore, for the smooth progress of the epitaxial silicon growth process, the bottom of the second groove 42 is processed. That is, the first inclined plane 43 is fabricated at the bottom of the second groove 42 through a dry etching process or wet etching process, etc. To fabricate the SNC, both the active region and the shallow trench isolation region are exposed at the bottom of the second groove 42 (referring to the structure on the left side of FIG. 2). The material of the active region generally is monocrystalline silicon, and the material of the shallow trench isolation region generally is oxide (for example, silicon dioxide). The active region and the shallow trench isolation region provide completely different environments for the growth of the epitaxial silicon. In the embodiments of the present disclosure, in this process, the monocrystalline silicon generally grows only on one side of the monocrystalline silicon, and the monocrystalline silicon is hard to grow or grows at a slow rate on one side of the silicon dioxide. Therefore, to provide more crystal orientations for the growth of the monocrystalline silicon and to ensure the growth of the monocrystalline silicon more uniform and more rapid, in the embodiments of the present disclosure, the first inclined plane 43 is fabricated before the epitaxial silicon growth process.

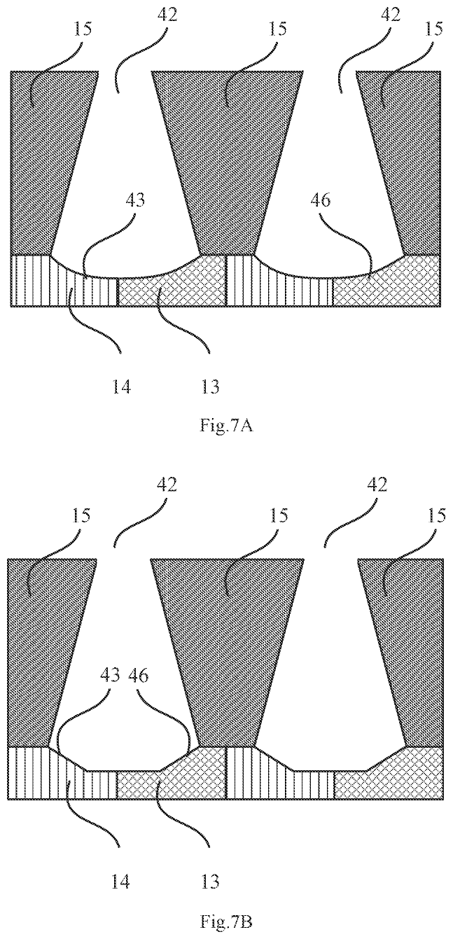

In an exemplary embodiment of the present disclosure, gas for etching the first inclined plane 43 may be, for example, sulfur hexafluoride (SF6). The first inclined plane 43 whose inclination angle is 30°-40° may be etched by controlling parameters such as bias and flow of the etching gas. It is to be noted that in the etching process, generally it is unable to ensure that a perfect plane is etched. Therefore, in the actual fabrication processes, the first inclined plane 43 may also be a cambered surface formed by the etching process, wherein the shape of the cambered surface may be as shown in FIG. 7A. In addition, in some embodiments, the active region also likely has other regions such as planes. That is, an end point of the first inclined plane 43 formed by etching does not coincide with an edge of the active region. In this case, the state of the active region may be as shown in FIG. 7B.

In addition, since the shallow trench isolation region is connected to the active region, it is easy to simultaneously etch the exposed part of the shallow trench isolation region when the inclined plane is etched at the exposed part of the active region. In this case, an etching selectivity may be controlled to be, for example, 1:1 to form the second inclined plane 46. The inclination angle of the second inclined plane 46 is, for example, 20°-60°. Of course, those skilled in the art should understand that due to process deviation or the etching selectivity not being 1:1, there exists a difference between a height of the shallow trench isolation region and that of the active region after etching. However, to prevent the shallow trench isolation region from greatly differing from the active region in height, the etching selectivity had better not differ greatly, lest air gaps are formed in the epitaxial silicon growth process. Similar to the formation of the first inclined plane 43, the second inclined plane 46 may also be a cambered surface, or the edge of the second inclined plane 46 does not coincide with the edge of the shallow trench isolation region. Reference may be made to FIG. 7A and FIG. 7B respectively for these two states.

It is to be understood that the etching process is conducted for the entire exposed part of the active region and the entire exposed part of the shallow trench isolation region. Therefore, the inclined plane at the bottom of the second groove 42 actually is similarly shaped like a bowl placed upright. There exists an inclined plane at the bottom of the second groove 42 no matter it is viewed from the cross section in the Direction A-A in FIG. 1 or it is viewed from the cross section in the Direction B-B in FIG. 2.

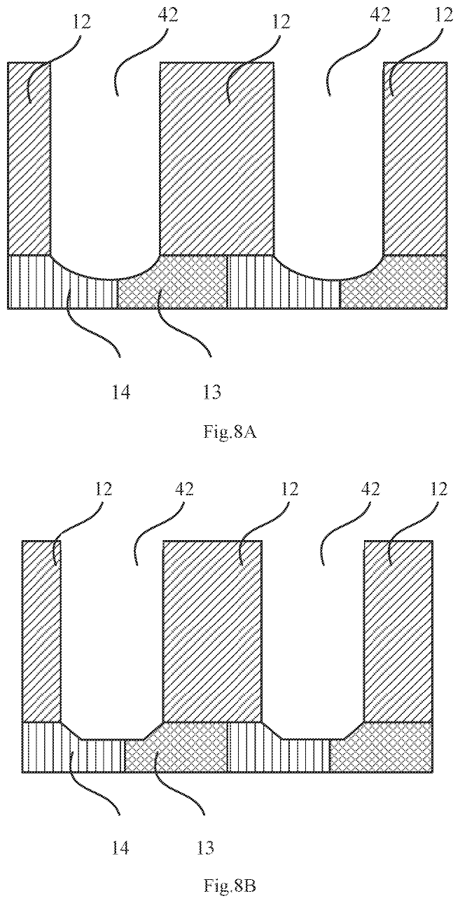

Reference may be made to FIG. 8A and FIG. 8B, viewed from the cross section in the Direction A-A on the left side of FIG. 1, the active region 14 and the shallow trench isolation region 13 may have different proportions and different inclined planes.

To prevent the remaining impurities (such as a natural oxide layer and etching residue) (At position of 43 or 46 in FIG. 6D) from having a negative effect on electrical properties of the inclined plane and even causing failed growth of the monocrystalline silicon, in some embodiments of the present disclosure, the first inclined plane 43 also may be cleaned in situ by means of dry cleaning of oxides or dry cleaning of removing carbon-based residues, etc., to ensure the purity of the monocrystalline silicon interface and to obtain high-quality growth effects.

After the in-situ cleaning, the monocrystalline silicon may grow taking the inclined plane as the substrate until the epitaxial silicon is controlled to fill the entire second groove 42 up to form the conductive plug 11 as shown in FIG. 4. In some embodiments, the conductive plug 11 is a storage node contact (SNC) structure. With reference to the right side of FIG. 1, viewed from the cross section of the Position A-A, there also exists an inclined plane below the conductive plug 11 (i.e., the SNC structure 11) as shown on the right side of FIG. 1.

It is to be noted that the shape of the grown monocrystalline silicon often is not ideal (as shown in FIG. 7), in another embodiment of the present disclosure, a growth selectivity of the polycrystalline silicon may be reduced in step S4, and a growth rate may be increased. For example, the growth selectivity may be reduced by setting an appropriate flow of hydrochloric acid. An exemplary concentration of the hydrochloric acid is, for example, 150 sccm±30%. Increase of the flow of the hydrochloric acid may inhibit the growth of polycrystals and tend to grow on the surface of a monocrystal. Decrease of the flow of the hydrochloric acid may increase the growth rate of the polycrystalline silicon and increase the yield. Therefore, it is required to seek the most appropriate flow range of the hydrochloric acid to ensure the quality of the monocrystal and to increase the yield. Therefore, the above range is set in the embodiments of the present disclosure.

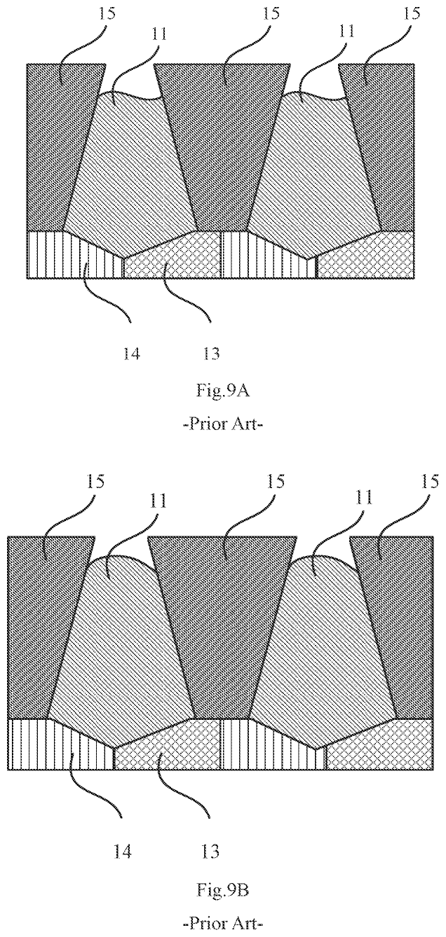

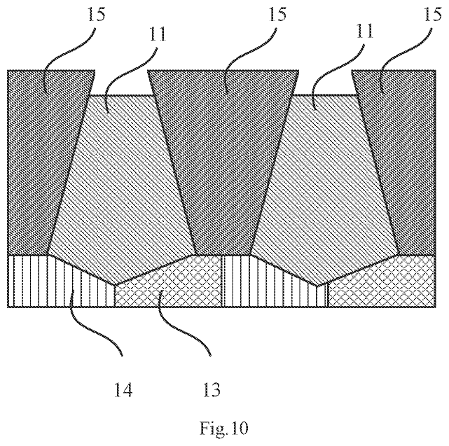

In addition, the monocrystalline silicon and the polycrystalline silicon may grow at the same time, and thus their shapes are not easy to control, as shown in FIG. 9A or FIG. 9B. In this case, the polycrystalline silicon may be removed by means of recess etch such as a wet process to only leave the monocrystal silicon, and the shape of the top of the monocrystalline silicon may be trimmed to a plane roughly (as shown in FIG. 10), and the length of the conductive plug is adjusted for the subsequent metal connection process.

In one embodiment, the conductive plug is a storage node contact. After the storage node contact is formed, a capacitive landing pad made of a metal material may be formed on the storage node contact for subsequent fabrication of a capacitor on the interface platform. The connection of the landing pad made of the metal material onto the storage node contact belongs to the fabrication of a metal-semiconductor contact structure. Therefore, in another embodiment of the present disclosure, after filling the second groove, metal may be deposited on the surface of the conductive plug 11.

In this case, the above-mentioned landing pad is in contact with the monocrystalline silicon, which is a case where metal is in contact with the monocrystalline silicon, similar to the case of contact between a source and a drain of a transistor in a peripheral circuit. Meanwhile, a metallization process is implemented, and optimal process conditions may be achieved at the same time, which makes process condition requirements simpler, improves the performance of the contact structure, and allows a contact resistance between the metal and the monocrystalline silicon to be smaller under the condition of lower fabrication costs.

In summary, in the embodiments of the present disclosure, the monocrystalline silicon is grown at the bottom of the groove to fabricate a storage node contact structure (SNC structure) that fills the groove up, which can avoid degradation of electrical properties caused by air gaps formed in the SNC structure due to deposition of the polycrystalline silicon in the related technologies. In addition, by fabricating an inclined plane of the monocrystalline silicon at the bottom of the groove and growing the monocrystalline silicon on the inclined plane of the monocrystalline silicon, problems such as uneven growth and low growth rate caused in the growth process of the monocrystalline silicon may be avoided, and a fabrication efficiency can be effectively enhanced while improving the yield rate.

It is to be noticed that although a plurality of modules or units of the device for action execution have been mentioned in the above detailed description, this partition is not compulsory. Actually, according to the embodiments of the present disclosure, features and functions of two or more modules or units as described above may be embodied in one module or unit. Reversely, features and functions of one module or unit as described above may be further embodied in more modules or units.

Other embodiments of the present disclosure will be apparent to those skilled in the art from consideration of the specification and practice of the invention disclosed here. This application is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the claims.

### INDUSTRIAL APPLICABILITY

According to the embodiments of the present disclosure, an inclined plane is arranged in the exposed part of the active region at the bottom of the groove containing the SNC structure, and the polycrystalline silicon is grown inside the groove by taking the inclined plane as a substrate. In this way, the SNC structure containing no air gap can be quickly formed, a component failure rate can be reduced, and a yield rate can be enhanced.

What is claimed is:

1. A semiconductor structure, comprising:
a substrate comprising an active region and a shallow trench isolation region spaced apart from each other;
a plurality of isolation structures arranged on a surface of the substrate;
a plurality of grooves arranged between the plurality of isolation structures, a bottom of one groove having a first inclined plane, and the first inclined plane being formed in the active region; and
a conductive plug arranged in the groove.

2. The semiconductor structure according to claim 1, wherein a top area of the groove is smaller than a bottom area thereof

3. The semiconductor structure according to claim 1, wherein an inclination angle of the first inclined plane is 30°-40°.

4. The semiconductor structure according to claim 1, wherein the bottom of the groove further has a second inclined plane, and the second inclined plane is formed in the shallow trench isolation region.

5. The semiconductor structure according to claim 4, wherein inclination angle of the second inclined plane is 20°-60°.

6. The semiconductor structure according to claim 1, wherein one of the plurality of isolation structures comprises a bit line structure and a dielectric layer structure.

7. The semiconductor structure according to claim 1, wherein cross sections of the plurality of grooves comprise one or more of a square, a polygon, a circle, or an ellipse.

8. The semiconductor structure according to claim 7, wherein the plurality of grooves are arranged in an array.

9. The semiconductor structure according to claim 1, wherein the first inclined plane is a cambered surface.

10. A fabrication method for fabricating a semiconductor structure, comprising:
providing a substrate, the substrate comprising an active region and a shallow trench isolation region spaced apart from each other;
forming a sacrificial layer material on a surface of the substrate;
etching a part of the sacrificial layer material to form a plurality of first grooves;
after depositing a dielectric layer on the plurality of first grooves, removing the remaining sacrificial layer material to form a plurality of second grooves;
etching down an exposed part of the active region at a bottom of one of the plurality of second grooves to form a first inclined plane; and
performing an epitaxial silicon growth process in the second groove to fill the second groove by using the first inclined plane as a base.

11. The fabrication method according to claim 10, wherein an inclination angle of the first inclined plane is 30°-40°.

12. The fabrication method according to claim 10, wherein the etching down an exposed part of the active region at a bottom of one of the plurality of second grooves to form a first inclined plane further comprises:
simultaneously etching an exposed part of the shallow trench isolation structure adjacent to the exposed part of the active region to form a second inclined plane.

13. The fabrication method according to claim 12, wherein an etching selectivity of the exposed part of the active region with respect to that of the exposed part of the shallow trench isolation structure is 1:1.

14. The fabrication method according to claim 10, wherein the performing an epitaxial silicon growth process in the second groove comprises:
setting a hydrochloric acid flow rate as 150 sccm±30%.

15. The fabrication method according to claim 10, wherein the performing an epitaxial silicon growth process in the second groove comprises:
after filling the second groove, removing a polycrystalline silicon by using a wet process to leave only a monocrystalline silicon, and trimming a top of filled silicon to be a flat plane.

16. The fabrication method according to claim 10, wherein after filling the second groove, the fabrication method further comprises:
depositing metal on a surface of filled silicon.
